(19) United States
(12) Patent Application Publication
(10) Pub. No.: US 2006/0168499 A1
(43) Pub. Date: Jul. 27, 2006

(54) Data archive verify software

(76) Inventors: Jathan D. Edwards, Afton, MN (US); Garry R. Lundstrom, Forest Lake, MN (US); Gregory D. Hanson, Mounds View, MN (US); Michael R. Rasmussen, Hastings, MN (US)

Correspondence Address: Imation Corp., PO Box 64898, St. Paul, MN, 55164-0898, US

(21) Appl. No.: 11/045,178

(22) Filed: Jan. 27, 2005

(51) Int. Cl. G11C 29/00

(52) U.S. Cl. 714/763

(57) ABSTRACT

The invention is directed to verify software to determine the quality and accuracy of data recorded on an optical data storage disk by an optical disk drive. A verify software module receives error information from the optical disk drive indicative of errors associated with the recovered data. The verify software module then generates an indication of data integrity based on the error information and presents the indication to a user of the optical disk drive via an output device. The data integrity indication identifies whether or not the data was recorded correctly and predicts how long the data will last. The indication is especially useful for data storage applications where reliable data archive is vital. The verify software may be distributed as a CD-ROM included with a multi-disk package of optical disks. The verify software CD-ROM may include a tutorial to be presented to the user via the output device.

### TECHNICAL FIELD

The invention relates to optical recording drives for optical data storage disks and, more particularly, techniques to identify and improve optical data integrity.

### BACKGROUND

Data storage media are commonly used for storage and retrieval of data, and come in many forms, such as magnetic tape, magnetic disks, optical tape, optical disks, holographic disks, cards or tape, and the like. Optical disks have generally gained widespread acceptance for data storage or data backup by individuals. Optical disks allow much quicker access to stored data than sequentially read magnetic tape, and can be a low cost data storage media alternative for individuals or large companies. Optical disks are especially useful for storing frequently-accessed data, and are also very useful for transferring data from one user to another.

Optical disks include, for example, audio CD (compact disc), CD-R (CD-recordable), CD-ROM (CD-read only memory), DVD (digital versatile disk or digital video disk) media, DVD-RAM (DVD-random access memory), and various types of rewritable media, such as CD-RW (CD-rewritable), magneto-optical (MO) disks, phase change optical disks and others. Some newer formats for optical data storage disks have storage capabilities on both sides of the disk. In addition, some newer formats are progressing toward smaller disk sizes. In some cases, multiple storage layers can be formed on a common side of optical data storage disks to improve storage capacity. Many new formats boast improved track pitches and increased storage density using blue-wavelength lasers for data readout and/or data recording. Examples of these so called “blue disks” include Blu-Ray and HD-DVD. As used herein, the term blue disk media (or blue disks) refers to optical disk media having a data storage capacity of greater than 15 gigabyte (GB) per data storage layer of the disk. A wide variety of optical data storage disk standards have been developed and other standards will continue to emerge.

A number of companies offer user recording or “burning” software, such as Nero from Ahead Software AG of Karlsbad-Itterbach, Germany, and Easy Media Creator from Roxio, Inc. of Santa Clara, Calif., USA. The recording software packages provide a simple interface for users to easily transfer data of various formats onto optical disks. Upon readout of an optical disk, an error correction code (ECC) functions to correct raw errors in the recovered data. If the raw error rate is less than a specified level, the ECC may be expected to reconstruct the data file in an error free condition. However, if the raw error rate exceeds the specified correctable level, the ECC may be unable to reconstruct an error free data file.

### SUMMARY

In general, the invention is directed to verify software to determine the quality and accuracy of data recorded on an optical data storage disk by an optical disk drive. A verify software module receives error information from the optical disk drive indicative of errors associated with the recorded data. The verify software module then generates an indication of data integrity based on the error information and presents the indication to a user of the optical disk drive via an output device. In some cases, the verify software module may communicatively couple directly to the optical disk drive. In other cases, the verify software module may communicatively couple to the optical disk drive via a recording software module that provides recording instructions to the optical disk drive.

Conventionally, the only data quality assurance for a user of a recorded disk may be playback of the recorded data to verify that the data is not corrupted. Some optical media companies have issued various claims about the durability or lifetime advantages of their media offerings, but such claims are often without substantial supporting documentation outside of controlled laboratory conditions. Furthermore, the quality of the optical recording may be highly dependent on the recording conditions such as recording speed, drive firmware, media handling, etc. The invention described herein presents a user with an indication of the quality of the recorded data and uses a predictive calculation to suggest how long the data will last. The indication is especially useful for data storage applications where reliable data archive is vital. The indication may comprise a graphical indication such as a green, yellow, or red indication corresponding to a high, medium, or low quality recording, respectively. In addition, the described verify software presents an indication that identifies whether or not the data was recorded correctly. The indication informs a user of the number of uncorrectable data errors, which may comprise damaged data.

In addition, the verify software may present the user with recommendations for improving recording conditions, such as upgrading drive firmware and reducing recording speed, when the indication indicates poor data integrity. Furthermore, the verify software may provide recommendations for media handling and storage conditions conducive to preserving media life when the indication indicates good data integrity.

The verify software may be distributed as a CD-ROM included with a multi-disk package of optical disks (i.e., “free-ware”). The verify software CD-ROM may include a tutorial to be presented to a user via an output device. For example, the tutorial may include step-by-step recording instructions, a comparison of different optical media formats, internet links, manufacturer product information, and/or manufacturer contact information. The verify software CD-ROM may also include a region of the disk designated with a test sequence that enables a user to test the performance of the optical disk drive.

In other cases, the software module may be incorporated as an archive specific function in a conventional recording software package. Furthermore, the verify software described herein may be a component of an optical disk system designed to provide archive solutions. The techniques could also be embodied in hardware of an optical disk system.

In one embodiment, the invention is directed to a method comprising receiving error information from an optical disk drive indicative of errors associated with data recorded on an optical disk by the optical disk drive. The method further comprises generating an indication of integrity of the data based on the error information.

In another embodiment, the invention is directed to a system comprising an optical disk drive to record data on an optical disk and a verify software module communicatively coupled to the optical disk drive. The verify software module receives error information from the optical disk drive indicative of error associated with data recorded on the optical disk and generates an indication of integrity of the data based on the error information.

In another embodiment, the invention is directed to a computer-readable medium containing instructions. The instructions cause a processor to receive error information from an optical disk drive indicative of errors associated with data recorded on an optical disk by the optical disk drive. The instructions further cause the processor to generate an indication of integrity of the data based on the error information.

The invention may be capable of providing one or more advantages. For example, the verify software module presents a simple interface to a user of an optical disk drive that indicates both a quality and an accuracy of data recorded on an optical disk. In this way, the described invention comprises a monitoring tool that provides an indication of when a user should perform another data backup. Furthermore, a verify software CD-ROM may include a region of the disk designated with a test sequence to test the performance of the optical disk drive. A user may be prompted to perform the disk drive test after a pre-determined number of recordings with poor data integrity have been indicated. In some embodiments, the user may be prompted to perform the disk drive test whenever a poor data integrity recording is indicated. In either case, the test sequence may be used to save a user time and money by quickly determining if the optical disk drive, and not the media or data, is responsible for the poor data integrity.

The details of one or more embodiments of the invention are set forth in the accompanying drawings and the description below. Other features, objects, and advantages of the invention will be apparent from the description and drawings, and from the claims.

### BRIEF DESCRIPTION OF DRAWINGS

FIG. 1 is a block diagram illustrating an exemplary data recording system.

FIG. 2 is a block diagram illustrating an example verify module in greater detail.

FIG. 3 is a flowchart illustrating an example operation of the verify module from FIG. 2.

FIG. 4 is a flowchart illustrating an example operation of a data lifetime module within a verify module.

FIG. 5 is a flowchart illustrating an example operation of a data error module within a verify module.

### DETAILED DESCRIPTION

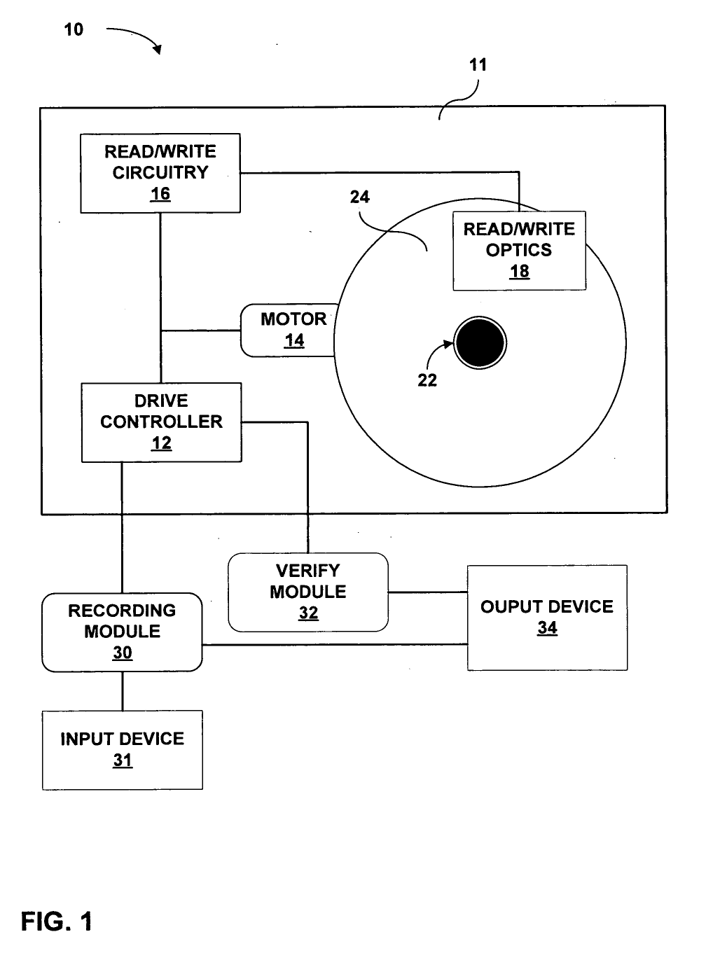

FIG. 1 is a block diagram illustrating an exemplary data recording system 10. In some embodiments, system 10 may comprise a data archiving system. Recording system 10 includes an optical disk drive 11, a recording module 30, a verify module 32, and an output device 34. In the illustrated embodiment, optical disk drive 11 comprises an optical recording drive. In some embodiments, optical disk drive 11 may comprise a conventional optical recording drive, which may be purchased as an off-the-shelf component from one of a number of disk drive manufactures, such as BenQ Corporation of Taipei, Taiwan, Pioneer Corporation of Tokyo, Japan, and Lite-On Technology Corporation of Taipei, Taiwan.

In the illustrated embodiment, optical disk drive 11 includes an optical data storage disk 24 positioned on a spindle 22. Optical disk 24 may comprise a CD-R, CD-RW, DVD-R, DVD-RW, Blu-Ray disk, HD-DVD, magneto-optical (MO) disk or another recordable media format. Optical disk drive 11 includes a drive controller 12, a spindle motor 14, read/write circuitry 16, and read/write optics 18. Spindle motor 14 rotates optical disk 24 around spindle 22. Drive controller 12 controls read/write circuitry 16, which in turn positions and controls read/write optics 18 to facilitate optical reading and writing of data to and from optical disk 24. Read/write optics 18 may include one or more lasers, one or more photosensitive elements, and various optical conditioning elements that facilitate optical data storage and readout. Read/write optics 18 may comprise a light source and an objective lens to focus the light onto a surface of optical disk 24.

Recording module 30 provides recording instructions to drive controller 12, in response to input from a user via input device 31. Recording module 30 may provide a simple interface for a user to easily transfer data of various formats onto optical disk 24 through input device 31. Input device 31 may comprise a keyboard, mouse, trackball, or any other input device used in optical disk recording. Recording module 30 may present information to the user via output device 34, which may comprise a display.

Recording module 30 may also include an error correction code (ECC) that functions to correct raw errors in the recovered data retrieved from optical disk 24. For example, recording module 30 may comprise commercial recording or “burning” software, such as Nero from Ahead Software AG of Karlsbad-Itterbach, Germany and Easy Media Creator from Roxio, Inc. of Santa Clara, Calif., USA. Recording module 30 may have been loaded onto system 10 from a CD-ROM or another computer-readable medium included with an after-market optical disk drive, e.g., optical disk drive 11.

Verify module 32 communicatively couples directly to drive controller 12 of optical disk drive 11. In other embodiments, verify module 32 may couple to optical disk drive 11 via recording module 30. Verify module 32 may comprise data recording verification software that may have been loaded onto system 10 from a CD-ROM or another computer-readable medium included with a multi-disk package of optical data storage disks (e.g., a multi-disk spindle) as “free-ware.” Multi-disk packages are available from a variety of optical disk manufacturers, such as Imation Corp. of Oakdale, Minn.

Verify module 32 performs read verification on optical disk 24 and receives error information from optical disk drive 11 indicative of errors associated with data recorded on optical disk 24 by optical disk drive 11. The read verification may be performed at the full read speed allowed by optical disk drive 11 rather than the 1× speed use to conventionally read the data. The error information may include first information indicative of pre-corrected errors associated with the data, such as PISum 8 errors (parity inner errors summed over 8 blocks) or BLER (Block Error Rates). The error information may also include second information indicative of post-corrected errors associated with the data, such as POF (parity outer failure) errors. The pre-corrected errors include errors in raw data recovered from optical disk 24 before an ECC algorithm is applied to the recorded data by recording module 30. Once the ECC algorithm is applied to the data recovered from optical disk 24, any remaining errors are considered post-corrected errors and typically comprise uncorrectable damage to the recovered data.

Verify module 32 determines the quality and accuracy of the data recorded on optical disk 24. More specifically, verify module 32 generates an indication of data integrity based on the error information indicative of pre-corrected error (e.g., PISum8) and post-corrected errors (e.g., POF). For example, verify module 32 may calculate an estimate for a life expectancy of the data based on the pre-corrected errors and a predicted error growth rate associated with the media type of optical disk 24. Verify module 32 also identifies one or more uncorrectable data errors based on the post-corrected errors. Verify module 32 then uses output device 34 to present the data integrity indication to the user of optical disk drive 11.

Verify module 32 may also present recommendations to the user depending on the data integrity indication. For example, when the indication indicates good data integrity, the recommendations may include handling precautions, storage preferences, and additional copy prompts as a means to realize full media lifetime potential. When the indication indicates poor data integrity, the recommendation may include drive firmware upgrades and recording speed reductions.

Output device 34 may comprise a desk-top monitor, a flat-screen display, a speaker, a printer, a fax machine, a docking station for a handheld computer, a memory drive, or the like. In most embodiments, output device 34 may present a graphical interface to the user of optical disk drive 11. In this case, output device 34 can present the data integrity indication determined by verify module 32 as a graphical indication. For example, output device 34 may present a green indication corresponding to a high quality recording, a yellow indication corresponding to a medium quality recording, or a red indication corresponding to a low quality recording. In some cases, output device 34 may present the estimated data life expectancy and the number of uncorrectable data errors as numerical representations. Many other graphical representations could be used to convey data integrity information to the user.

Some conventional recording software packages have tools that enable a user to see error information associated with data recorded on an optical disk by an optical disk drive as part of a tool-kit section of the software. However, the relevance of the error information eludes most users, especially end-users who are not necessarily educated in the metrics indicative of data integrity or the media degradation mechanisms that put data integrity at risk. In addition, during data file transfers commercial recording software presumably compares the recorded data against the original on a byte-by-byte bases, but this feature is time-consuming and not implemented for the most common applications of data archiving. Optical disk media companies can only assure typical lifetime expectations for data recorded under controlled conditions, e.g., on high quality recording drives with current firmware upgrades and using media unblemished by fingerprints and surface scratches.

The verify software described herein interprets the error information received from the user's particular optical disk drive and presents the user of the optical disk drive with a quick and easy-to-understand indication of recorded data integrity. The verify software uses a predictive calculation to determine how long the data will last and identifies whether or not the data was recorded correctly based on the raw and corrected error information, respectively, from the optical disk drive and the particular optical disk bearing the data.

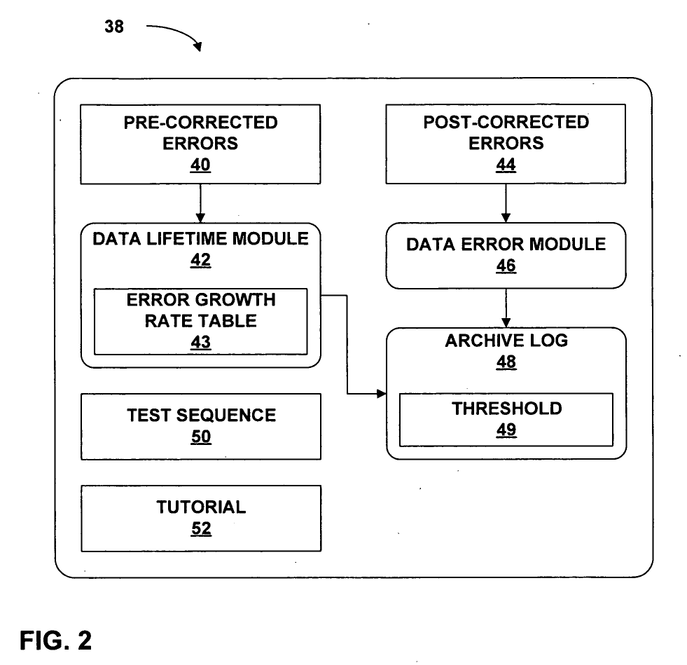

FIG. 2 is a block diagram illustrating an example verify module 38 in greater detail. Verify module 38 may correspond to verify module 32 from FIG. 1. Verify module 38 may comprise data recording verification software that performs read verification on recently recorded optical data storage disks. An expedited read verification may be performed at a full read speed allowed by an optical disk drive rather than the 1× speed used conventionally by consumers to manually verify recorded data, e.g., video or audio information.

Verify module 38 receives error information from an optical disk drive indicative of raw and corrected errors associated with data recovered from an optical disk by the optical disk drive. The error information includes first information indicative of pre-corrected errors 40 associated with the data and second information indicative of post-corrected errors 44 associated with the data. Verify module 38 interprets the received information 40, 44 and generates an indication of data integrity. Verify module 38 may present the indication to a user of the optical disk drive via an output device. The indication indicates the quality and accuracy of the recorded data.

In the illustrated embodiment, verify module 38 comprises a data lifetime module 42. Data lifetime module 42 includes an error growth rate table 43 that comprises different characteristics and rates of error growth for a variety of optical disk media types. Data lifetime module 42 predicts how long the data recorded on the optical disk will last. First, data lifetime module 42 selects an error growth rate from error growth rate table 43 that corresponds to the particular type of optical disk on which the data was recorded. Data lifetime module 42 then applies the selected error growth rate to pre-corrected errors 40 to calculate an estimate for a life expectancy of the data.

As one example, data lifetime module 42 may determine that data recorded on a particular type of optical disk with less than 50 pre-corrected errors (PISum8max) predicts a data life expectancy of more than twenty-five years. In that case, data lifetime module 42 may generate a first indication corresponding to a high quality recording. Further, data lifetime module 42 may determine that data recorded on the optical disk with between 150 and 50 pre-corrected errors predicts a data life expectancy between twenty-five years and ten years, which causes data lifetime module 42 to generate a second indication corresponding to a medium quality recording. Finally, data lifetime module 42 may determine that data recorded on the optical disk with more than 150 pre-corrected errors predicts a data life expectancy of less than ten years. Data lifetime module 42 then generates a third indication corresponding to a low quality recording.

The low quality recording may correspond to a recording with poor data integrity. In this way, verify module 38 may act as a monitoring tool that allows the user to schedule data backups based on the estimated life expectancies of each optical data storage disk. Of course, in other embodiments, the definitions of various levels of media quality or life expectancy may be defined in wide variety of ways. For example, since media lifetime expectations are dependent on storage and handling conditions, media lifetime indications may be expressed qualitatively with simplified indications such as long, medium, and short rather than quantitatively with a number of years.

Verify module 38 also includes a data error module 46. Data error module 46 identifies whether or not the data was recorded correctly on the optical disk. More specifically, data error module 46 identifies one or more uncorrectable data errors based on post-corrected errors 44 (e.g., POF). For example, data error module 46 may generate a perfect data correction indication when a recording has no uncorrectable data errors. Data error module 46 may generate a data error indication when a recording has more than zero uncorrectable data errors. The data error indication may correspond to a recording with poor data integrity. Various levels of data error may also be defined, if desired.

Verify module 38 presents the data integrity indication to the user via the output device (not shown in FIG. 2). The indication may include the life expectancy indication generated by data lifetime module 42 and the accuracy indication generated by data error module 46. In some cases, each of the indications may comprise a graphical representation presented to the user on a desktop monitor or flat-screen display. In one simple example, the high quality recording may correspond to a green indication, the medium quality recording may correspond to a yellow indication and the low quality recording may correspond to a red indication. In other cases, verify module 38 may present a numerical representation of the predicted life expectancy and the uncorrectable data errors to the user. In other embodiments, other graphical or audio representations may be associated with the indications. The indications are preferably simple, so that unsophisticated users can easily understand the indications without requisite knowledge of jitter, BLER, or PISum8 media metrics or degradation models predicting media lifetimes.

Verify module 38 includes an archive log 48 that stores initial recording conditions, the pre-ECC, and the post-ECC error information associated with the recovered data. Data lifetime module 42 and data error module 46 update archive log 48 with the data integrity indication for each recording performed by the optical disk drive. Therefore, archive log 48 maintains a number of poor data integrity recordings generated by the optical disk drive.

When either data lifetime module 42 or data error module 46 generates an indication of poor data integrity, the output device may prompt the user to re-record the data. Furthermore, archive log 48 includes a threshold value 49. When the number of poor data integrity recordings included in archive log 48 exceeds the predetermined threshold value 49, verify module 38 may prompt the user to perform a test sequence 50 on the optical disk drive. Archive log 48 may also present the user with recommendations to improve recording conditions based on the initial recording conditions included in archive log 48. In other cases, the user may perform test sequence 50 on the optical disk drive at any time to test the optical disk drive for recording integrity.

Running test pattern 50 on the optical disk drive determines whether the optical disk or the optical disk drive is responsible for the relatively poor data integrity of the archived data. In this way, the user may easily determine whether the optical disk drive is the cause of repeated recording problems, and whether a new optical disk drive is required for reliable data archive.

In the illustrated embodiment, verify module 38 also includes a tutorial 52, which may be presented to the user via the output device. For example, the output device may present tutorial 52 to the user when the recording module initiates a data recording session. In other cases, the user may request the presentation of tutorial 52. Tutorial 52 may include recording instructions for improved recording conditions, a comparison of different optical media formats, internet links for software downloads or advertising information, manufacturer product information, and/or manufacturer contact information. Tutorial 52 may provide useful information to a user, and may also present an advertising opportunity to the creator of verify module 28.

Verify module 38 may be loaded onto a recording system from a CD-ROM or another computer-readable medium. For example, verify module 38 may be included with a multi-disk package of optical disks. In other cases, verify module 38 may be incorporated as an archive specific function in a conventional recording software package. Furthermore, verify module 38 may be a component of a recording system designed to provide archive solutions. Similar verify functionality could also be implemented as hardware of an optical drive, although software is more generally preferred.

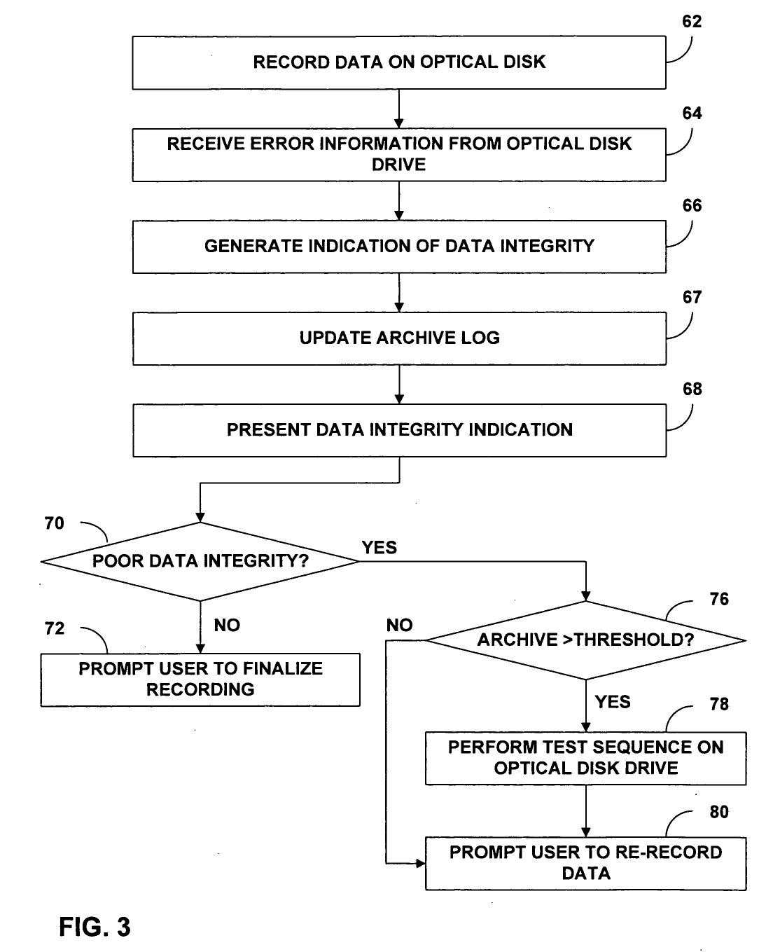

FIG. 3 is a flow chart illustrating an example operation of verify module 38 from FIG. 2. As described above, verify software module 38 may be loaded onto a recording system. The recording system may comprise an optical disk drive and a recording software module, e.g., substantially similar to recording system 10 from FIG. 1. The optical disk drive records data on an optical disk (62) according to instructions received from the recording module. Verify module 38 may present tutorial 52 to a user via an output device. In some cases, verify module 38 may present step-by-step tutorial 52 during a recording session initiated by the recording module. In other cases, tutorial 52 may be presented upon receiving a request from the user.

Once the recording session is complete, verify module 38 receives error information from the optical disk drive indicative of errors associated with the data recorded on the optical disk (64). The error information may include first information indicative of pre-corrected errors 40 associated with the data and second information indicative of post-corrected errors 44 associated with the data.

Verify module 38 then uses data lifetime module 42 and data error module 46 to generate an indication of data integrity based on the received error information (66). For example, data lifetime module 42 calculates an estimate for a data life expectancy based on pre-corrected errors 40 and an error growth rate corresponding to the particular type of optical disk. The error growth rate may be predicted or estimated for different optical disk media types. Further, data error module 46 identifies one or more uncorrectable data errors based on the post-corrected errors 44.

Data lifetime module 42 and data error module 46 update archive log 48 with the data integrity indication (67). Archive log 48 also stores initial recording conditions, the pre-ECC, and the post-ECC error information associated with the recovered data. Verify module 38 then directs the output device to present the indication of data integrity to the user (68). The presented indication may comprise an easy-to-understand graphical or audio indication that interprets the error information received from the recording drive. The data integrity indication may inform the user of how long the recorded data will last and whether or not the data was recorded correctly.

For example, the indication may comprise a graphical indication such as a green, yellow, or red indication corresponding to a high, medium, or low quality recording, respectively. Each of the quality indications may represent a data life expectancy or data life expectancy range. The indication may also comprise the number of uncorrectable data errors on the optical disk, which may comprise damaged data.

When verify module 38 generates an indication of a recording with good data integrity (no branch of 70), verify module 38 prompts the user (via an output device) to finalize the recording (72). Verify module 32 may also present recommendations to the user including handling precautions, storage preferences, and additional copy prompts as a means to realize full media lifetime potential.

In the case where verify module 38 generates an indication of a recording with poor data integrity (yes branch of 70), verify module 38 compares the number of poor data integrity recordings included in archive log 48 with predetermined threshold value 49 (76). As an example, a low quality recording or a recording with more than zero uncorrectable data errors may correspond to a recording with poor data integrity. When the number of poor data integrity recordings included in archive log 48 is less than the predetermined threshold value 49 (no branch of 76), verify module 38 prompts the user via the output device to re-record the data either on a different format of optical disk or at a different speed (80).

When the number of poor data integrity recordings included in archive log 48 exceeds the predetermined threshold value 49 (yes branch of 76), verify module 38 prompts the user to perform test sequence 50 on the optical disk drive (78). Verify module 38 may present the results of test sequence 50 to the user via the output device. Regardless of the test pattern results, verify module 38 prompts the user to re-record the data either on a different format of optical disk, at a different speed, or on a different optical disk drive (80). Verify module 32 may also present recommendations to the user to improve recording conditions, such as upgrading drive firmware.

In some cases, verify module 38 may prompt the user to perform test sequence 50 on the optical disk drive each time the indication indicates poor data integrity. In other cases, the user may perform test sequence 50 on the optical disk drive at any time to test the optical disk drive for recording integrity. Performing test pattern 50 on the optical disk device determines whether the optical disk or the optical disk drive is responsible for the poor data integrity recordings.

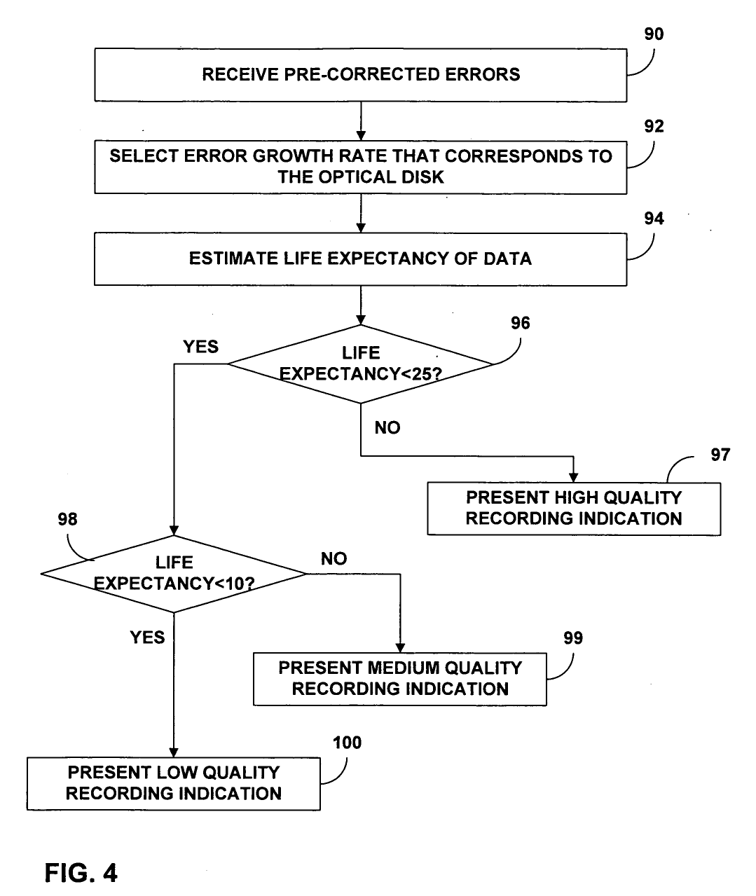

FIG. 4 is a flowchart illustrating an example operation of data lifetime module 42 within verify module 38 from FIG. 2. Data lifetime module 42 receives pre-corrected errors 40 associated with data recorded on an optical disk by an optical disk drive (90). Data lifetime module 42 includes error growth rate table 43 that comprises characteristics and rates of error growth for a variety of optical disk types. The characteristics and rates of error growth may be estimated or predicted by verify module 38.

Data lifetime module 42 selects an error growth rate from error growth rate table 43 that corresponds to a particular type of optical disk on which the data was recorded (92). Data lifetime module 42 then calculates an estimate for a data life expectancy based on the selected error growth rate and pre-corrected errors 40 (94).

Data lifetime module 42 presents the estimated data life expectancy to the user via the output device. As an example, when the life expectancy is greater than twenty-five years (no branch of 96), data lifetime module 42 presents a first indication corresponding to a high quality recording (97). As discussed above, the high quality recording may correspond to recordings with less then 50 pre-corrected errors. When the life expectancy is between twenty-five years and ten years (yes branch of 96, no branch of 98), data lifetime module 42 presents a second indication corresponding to a medium quality recording (99). The medium quality recording may correspond to recordings with between 50 and 150 pre-corrected errors. When the life expectancy is less then ten years (yes branch of 98), data lifetime module 42 presents a third indication corresponding to a low quality recording (100). The low quality recording may correspond to recordings with more than 150 pre-corrected errors 40. Again, the definitions of various levels of media quality or life expectancy may be defined in wide variety of ways in different implementations and embodiments.

In some cases, each of the quality indications may comprise a graphical representation. For example, the high quality recording may correspond to a green indication, the medium quality recording may correspond to a yellow indication, and the low quality recording may correspond to a red indication. In some cases, the output device presents the data life expectancy in a numerical format. In other embodiments, other graphical or audio representations may be associated with the indications.

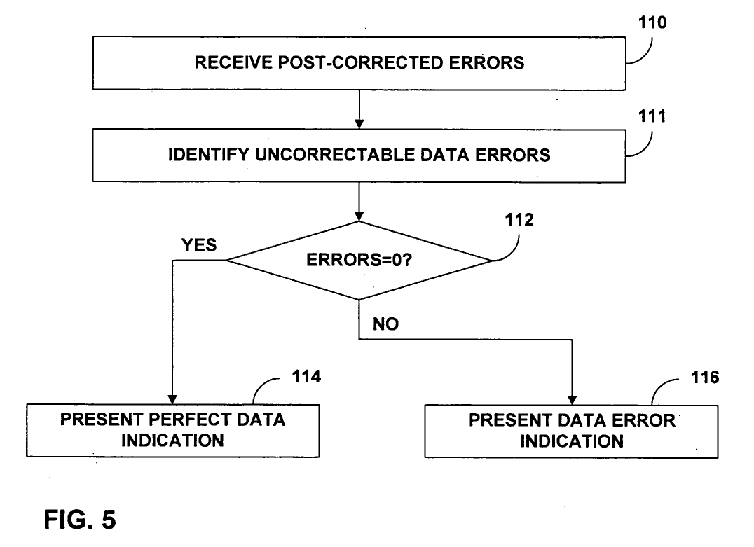

FIG. 5 is a flowchart illustrating an example operation of data error module 46 within verify module 38 from FIG. 2. Data error module 46 receives post-corrected errors 44 associated with data recorded on an optical disk by an optical disk drive (110). Data error module 46 identifies whether or not the data was recorded on the optical disk correctly. More specifically, data error module 46 identifies one or more uncorrectable data errors based on post-corrected errors 44. More specifically, data error module 46 identifies one or more uncorrectable data errors based on post-corrected errors 44 (111).

When the number of uncorrectable data errors equals zero (yes branch of 112), data error module 46 presents a perfect data correction indication to the user (114). The perfect data indication may correspond to a recording with correctable data integrity. When the number of uncorrectable errors is greater than zero (no branch of 112), data error module 46 presents a data error indication to the user (116). The data error indication may correspond to a recording with poor data integrity. In some cases, the accuracy indication may comprise a graphical or audio representation. In other cases, data error module 46 may simply present the number of uncorrectable data errors to the user. Various levels of data integrity could also be defined, e.g., with more post-corrected errors indicating poorer data integrity.

Various embodiments of the invention have been described. For example, verify software has been described that generates an indication of data integrity based on error information associated with data recorded on an optical disk by an optical disk drive. The verify software described herein receives the error information and interprets the error information to present a user with easy-to-understand indications of data life expectancy and readability.

Nevertheless various modifications can be made to the techniques described herein without departing from the spirit and scope of the invention. For example, although described herein for use in an optical disk recording system, the verify software may be applied to other recording systems including magnetic tape and magnetic disk recording systems. Also, the software may be used specifically with a newer blue media format drive. These and other embodiments are within the scope of the following claims.

1. A method comprising:
receiving error information from an optical disk drive indicative of errors associated with data recorded on an optical disk by the optical disk drive; and
generating an indication of integrity of the data based on the error information.

2. The method of claim 1, wherein:
the error information comprises information indicative of post-corrected errors associated with the data; and
the indication identifies whether or not the data was recorded correctly.

3. The method of claim 2, wherein generating the indication comprises identifying one or more uncorrectable data errors based on the post-corrected errors.

4. The method of claim 1, wherein:
the error information comprises information indicative of pre-corrected errors associated with the data; and
the indication comprises a prediction of how long the data will last.

5. The method of claim 4, wherein generating the prediction comprises calculating an estimate for a life expectancy of the data based on the pre-corrected errors and an error growth rate associated with the optical disk.

6. The method of claim 1, wherein receiving error information comprises receiving first information indicative of pre-corrected errors associated with the data and receiving second information indicative of post-corrected errors associated with the data.

7. The method of claim 1, further comprising presenting the data integrity indication via an output device.

8. The method of claim 7, wherein presenting the data integrity indication comprises presenting one of a first indication corresponding to a high quality recording, a second indication corresponding to a medium quality recording, and a third indication corresponding to a low quality recording.

9. The method of claim 8, wherein the first indication comprises a first color, the second indication comprises a second color, and the third indication comprises a third color, wherein the first, second, and third colors comprise substantially different colors.

10. The method of claim 1, further comprising prompting a user of the optical disk drive to re-record the data when the indication indicates poor data integrity based on the error information.

11. The method of claim 10, wherein prompting the user to re-record the data comprises prompting the user to re-record the data either on a different format of optical disk or at a different speed.

12. The method of claim 1, further comprising:
updating an archive log with the data integrity indication; and
running a test sequence on the optical disk drive when the archive log includes a pre-determined number of indications that indicate poor data integrity.

13. The method of claim 1, further comprising presenting a tutorial via an output device, wherein the tutorial comprises at least one of user recording instructions, a description of optical media formats, internet links, manufacturer product information, and manufacturer contact information.

14. A system comprising:
an optical disk drive to record data on an optical disk;
a verify software module communicatively coupled to the optical disk drive to receive error information from the optical disk drive indicative of error associated with data recorded on the optical disk and generate an indication of integrity of the data based on the error information.

15. The system of claim 14, further comprising an output device to present the indication generated by the verify software module.

16. The system of claim 14, wherein the error information comprises first information indicative of pre-corrected errors associated with the data and second information indicative of post-corrected errors associated with the data, and wherein the verify software module comprises:
a data lifetime module to calculate an estimate for a life expectancy of the data based on the pre-corrected errors and an error growth rate associated with the optical disk; and
a data error module to identify one or more uncorrectable data errors based on the post-corrected errors.

17. The system of claim 14, wherein the verify software module comprises:
an archive log updated with the data integrity indication; and
a recording drive test sequence that tests the optical disk drive when the archive log includes a predetermined number of indications that indicate poor data integrity.

18. A computer-readable medium comprising instructions that cause a processor to:
receive error information from an optical disk drive indicative of errors associated with data recorded on an optical disk by the optical disk drive; and
generate an indication of integrity of the data based on the error information.

19. The computer-readable medium of claim 18, wherein the computer-readable medium comprises a CD-ROM included with a multi-disk package of optical disks.

20. The computer-readable medium of claim 18, further comprising instructions that cause the processor to test the optical disk drive.
